(19) United States
(12) Patent Application Publication
(10) Pub. No.: US 2011/0224923 A1
(43) Pub. Date: Sep. 15, 2011

(54) PASSIVE INTERMODULATION TEST APPARATUS

(75) Inventors: Christine Blair, Murarrie Queensland (AU); Mostafa Mohamed Taher AbuShaaban, Runcorn Queensland (AU); Greg Delforce, Murarrie Queensland (AU); Peter Stanford, Murarrie Queensland (AU)

(73) Assignee: TRIASX PTY LTD.

(21) Appl. No.: 12/962,121

(22) Filed: Dec. 7, 2010

Related U.S. Application Data
(63) Continuation of application No. 11/936,968, filed on Nov. 8, 2007, now abandoned.

(51) Int. Cl. G01R 15/00

(52) U.S. Cl. 702/57

(57) ABSTRACT

In one aspect of the present invention there is provided a portable test apparatus 100 for a communications device/system said apparatus including, a display 103 for displaying test information from the communications device/system, a filter assembly 122 and a control assembly 124 comprising at least one printed circuit board and a housing wherein the at least one printed circuit board and the housing co-operate to electrically isolate one or more components disposed on said at least one printed circuit board.

### BACKGROUND OF THE INVENTION

1. Field of the Invention

The present invention relates generally to radio frequency communication systems. In particular although not exclusively the present invention relates to an apparatus for measuring sources of interference.

2. Discussion of the Background Art

Quality of Service (QOS) is of major importance to today's communication network providers. One of the major factors effecting QOS in most modern communication is interference. The two most appreciable forms of interference present in most communication systems result from Active and Passive intermodulation. In each case multiple transmitting frequencies combine in ways that cause interference to receiving equipment.

In the case of Active Intermodulation (AIM) interference the transmitter or receiver actively amplify interfering signals in the in the environment that cause harmful interference. Passive Intermodulation (PIM) interference is similar to active intermodulation interference except that it almost occurs exclusively in passive elements when two or more frequencies are simultaneously present. When signals F₁ and F₂ for example encounter a non-linear device they combine as follows, mF1±nF2, (m,n=1, 2, 3 . . . ) to produce interfering signals.

To date most suppliers of RF communications components have not been able to model PIM. One can only design components to reduce the possibility of significant levels of PIM being internally generated. Typically this reduction is achieved by applying lessons learnt from past experiences, and from testing the component presently under design. While it is possible to take account for PIM produced by each individual component during the system design phase, the effects of PIM which can be generated outside the components via poor interconnects etc, and when the component are installed on-site cannot be so easily accounted for.

Presently it has been relatively difficult to test for PIM on-site. Historically the equipment required to perform the testing was rather large and cumbersome and not readily suited for in-field deployment and has been widely considered by most in the communications industry as being impractical. Typically such on-site PIM testing requires each junction, line and interconnect to be checked. Without a PIM tester on-site, this operation is extremely labour intensive, requiring a technician to physically check/remake each connection as installed, and as such is extremely costly.

Clearly it would be advantageous to provide a device which allows for the on-site analysis of PIM interference along with other communication system parameters in a single unit and that it performs such testing in an efficient and cost effective manner.

### SUMMARY OF THE INVENTION

### Disclosure of the Invention

Accordingly in one aspect of the present invention there is provided a portable test apparatus for a communications device/system said apparatus comprising, a display for displaying test information from the communications device/system, a filter assembly and a control assembly comprising at least one printed circuit board and a housing wherein the at least one printed circuit board and the housing co-operate to electrically isolate one or more components disposed on said at least one printed circuit board.

Suitably the filter assembly and the control assembly are arranged in a stacked configuration relative to one another. Preferably the filter assembly and the control assembly are stacked in vertical relation. Most preferably the filter assembly and the control assembly are stacked linearly on top of one another.

Preferably the housing mates with one or more exposed surface regions provided on the PCB to electrically isolate one or more components disposed on said at least one printed circuit board.

The display maybe a flat panel touch screen PC, a tablet PC or the like. The display may include a dedicated display area for displaying information relating to the current test point within the device/system under test and/or one or more operating parameters of the apparatuses internal test modules. Suitably the display includes one or more buttons for navigating one or more menus provided within the unit's software. The display may also include a power on/off button for initiating and terminating the selected test mode.

Suitably the apparatus provides a plurality of selectable test modes including but not limited to a power test mode, a return loss test mode and a passive intermodulation test mode. The test modes being selectable via the use the navigation buttons provided on the display. The apparatus may include a restricted and a non-restricted user level. Preferably under the restricted user access level, a user may only alter test point and the test mode. Under the non-restricted the user may alter one or more operating parameters of the test unit including for example output power, output frequency (i.e. under the non-restricted user level a user is free to full customise the test apparatus set up).

Preferably the test apparatus provides at least two output frequency tones, selected from the radio communication frequency bands. For example the tones could be selected from a frequency range of about 800 MHz to 1000 MHz or from about 1700 MHz to 2200 MHz. In the case of the restricted access level the frequency tones may be preset, the preset values being consistent with operating frequency band license allocations for the device/system under test.

The apparatus may include at least one port for the attachment of an auxiliary device. The auxiliary device may be a spectrum analyser, a power meter or the like. The test apparatus may include at least one port as access to a built in low PIM load. Suitably the apparatus includes at least one network interface such as Ethernet Port or 802.11a, b, g or n interface. The apparatus may also include at least one serial interface such as a USB port, an RS232 serial port, a 1394 (Firewire) interface or the like.

The filter assembly preferably includes a combiner and a set of transmission and reception filters. Suitably the filter assembly includes at least two transmission filters. The transmission filters may be provided as separate filters or they could be a plurality of filters diplexed. Preferably the filter assembly includes at least two reception filters. The reception filters may be provided as separate filters or they could be plurality of filters diplexed. Suitably the transmission and reception filters are bandpass filters. The combiner may include at least one isolator and a coupler. Preferably the coupler is a 3 dB coupler and the isolator is a dual isolator.

The filter assembly may also include at least one Voltage Standing Wave Ratio (VSWR) monitor. The VSWR monitor may include at least one forward coupler and at least one reverse coupler. Suitably the at least one forward coupler and at least one reverse coupler are coupled to a detector/switching circuit.

The control assembly preferably includes at least one high power amplifier module. Suitably the high power amplifier module includes first high power amplifier circuit and second high power amplifier circuit in a parallel arrangement. Preferably the control assembly includes a voltage regulator module. Suitably the voltage regulator module provides a plurality of DC voltage rails including at least one +5V rail, at least one +12V rail and at least one +26V rail.

The control assembly may also include a frequency module and a receiver module. The frequency module may include at least one frequency synthesiser and at least one low noise amplifier and a reference oscillator. Preferably the frequency module includes a first frequency synthesiser and a second frequency synthesiser which are adapted to provide the output frequency tones. The frequency module may also include a third and fourth frequency synthesiser which are adapted to provide reference signals to the receiver module. Suitably the first and second frequency synthesisers are adapted to produce a frequency between 800 MHz to 1000 MHz or from about 1700 MHz to 2200 MHz, while the third and fourth frequency synthesiser are adapted to provide frequencies between 50 MHz to 100 MHz. Preferably the reference oscillator is adapted to provide a 10 MHz reference signal to each of the synthesisers. The receiver module may include at least one receiver circuit and a down converter circuit. The down converter preferably includes a mixer and a bandpass filter.

The control assembly may also include at least one temperature sensor and a current monitoring and gate control module. Suitably the temperature sensor and the current monitoring and gate control module are coupled via an I²C bus to an I²C bus controller. The bus controller may also be coupled to a plurality of detectors which monitor the operating status of one or more components/modules within the control assembly.

Preferably the high power amplifier module, frequency module, receiver module, voltage regulator module, temperature sensor, current monitoring and gate control module, I²C bus controller and the plurality of detectors are all disposed on the at least one printed circuit board within the control assembly.

Suitably the control assembly includes at least one main processor, which is responsible for the control of the various test modules and for the processing and displaying the received test information collected from the communications device/system under test.

The control assembly may include a first and a second printed circuit board. Preferably the plurality of modules within the control unit are split between the first printed circuit board and the second printed circuit board such that the first printed circuit board accommodates a number of modules and the second printed circuit board accommodates a number of modules. The housing may be constructed from a plurality of segments. Suitably the plurality of segments co-operate with the first and second printed circuit boards to electrically isolate one or more components/modules disposed on the first and second printed circuit board. Preferably the segments mate with one or more exposed surface regions on said first and second printed circuit boards to electrically isolate or more components disposed on said first and second printed circuit boards.

Throughout the specification the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

### BRIEF DETAILS OF THE DRAWINGS

In order that this invention may be more readily understood and put into practical effect, reference will now be made to the accompanying drawings, which illustrate preferred embodiments of the invention, and wherein:

FIG. 1 depicts one possible configuration of the front panel of the test apparatus according to one embodiment of the present invention;

FIG. 2 is a perspective view of one possible configuration of the test apparatus mounted within a carry case with lid attached according to one embodiment of the present invention;

FIG. 3 is a perspective view of the case housing the test apparatus with lid closed and handled extended for transport.

FIG. 4A is a bottom perspective view of the test apparatus according to one embodiment of the present invention;

FIG. 4B is a top perspective view of the test apparatus according to FIG. 4A;

FIG. 4C is a right side perspective view of the test apparatus according to FIGS. 4A and 4B;

FIG. 4D is a further bottom perspective view perspective view of the test apparatus according to FIGS. 4A to 4C;

FIG. 5 is a system schematic for the test apparatus of FIGS. 1 to 4D above

FIG. 6A is an exploded view of the main control section of the test apparatus according to embodiment of the present invention;

FIG. 6B is the reverse exploded view of the main control section of FIG. 6A;

FIG. 7 is a detailed view of a control PCB according to one embodiment of the present invention; and

FIG. 8 is a schematic block diagram of one possible arrangement of an internal cable load according to one embodiment of the present invention; and

FIG. 9 depicts one arrangement for an external cable load according to one embodiment of the present invention.

### DESCRIPTION OF EMBODIMENTS OF THE INVENTION

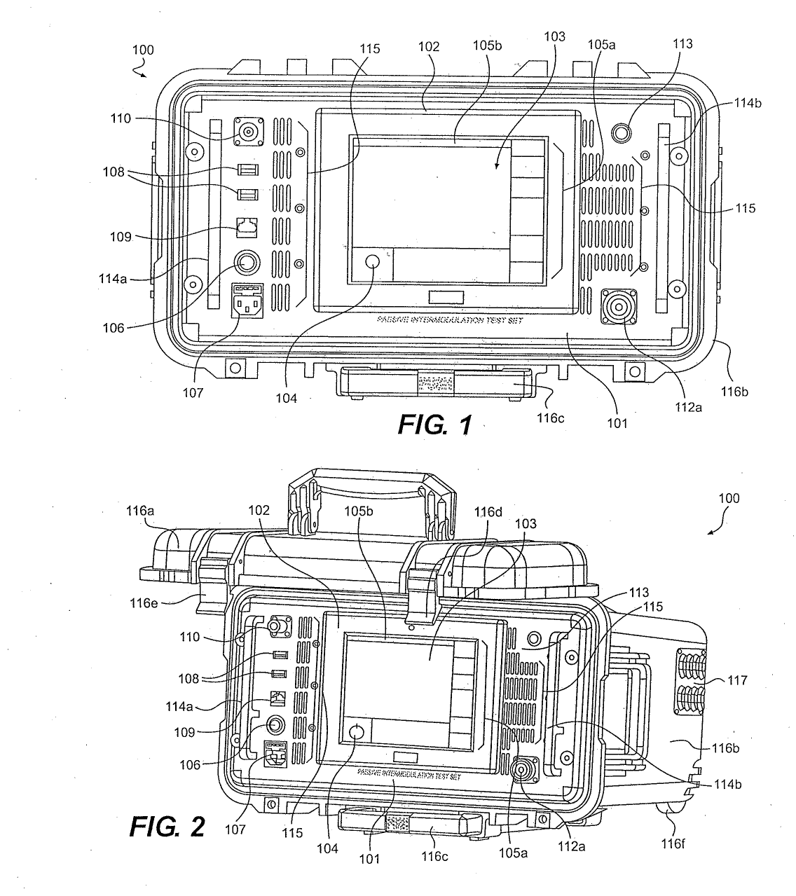

In reference to FIG. 1 there is illustrated one possible arrangement of a portable test unit 100 according to the present invention. As shown the test unit is mounted within a carry case 116 which has a securable lid 116b (not shown) and an extendable handle 116c.

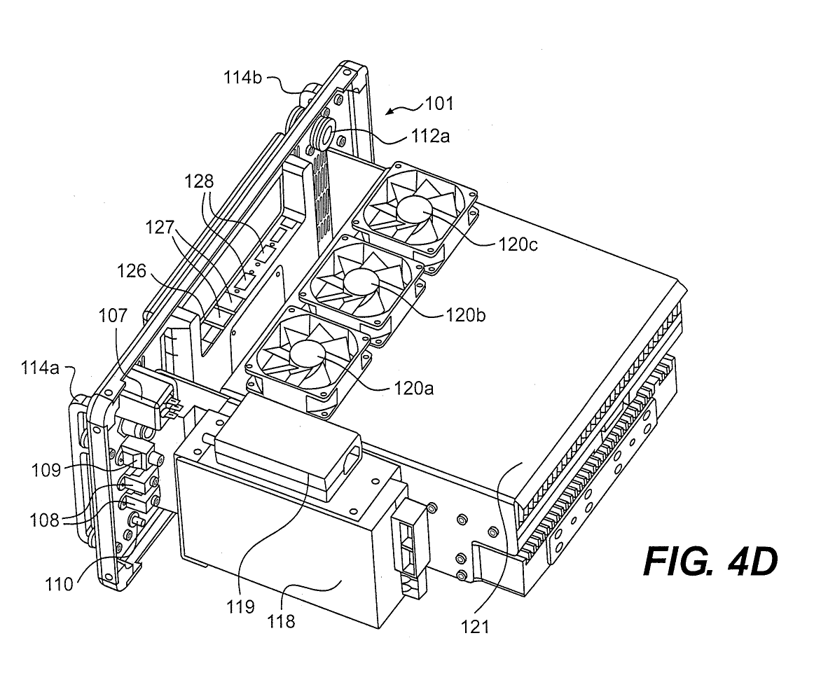

The test unit 100 is mounted such that front panel 101 is the only portion of the test unit 100 exposed during testing of the device/system of interest. In this particular instance the front panel 101 includes a flat panel touch screen computer 102, having main display 103 for displaying the measurement for a given parameter of the device/system under test, which is coupled to the output port 112a. Also provided on the front panel are mains power socket 107 and main power switch 106 which are coupled to the unit's main DC power supply 118 (see FIGS. 4A to 4D).

The main display 103 includes a power on/off button 104, which is used to start and stop the test procedure for the device/system of interest. The current test point is displayed in the header bar 105b of the display. Header bar 105b may also display information relating to the current operating status of various test modules hosed within the test unit 100. Also provided on the main display are a plurality of menu buttons 105a these buttons allow a user to navigate through the various reporting functions, change or assign new test points or configure various characteristics of the test unit 100 such as output power, output frequency, review of internal system alarms etc (depending on the users level of access). Presently the flat panel touch screen computer 102 runs a customised version of Windows XP®, it will be appreciated by those of ordinary skill in the art that any other operating platform may be utilised such as Windows Vista®, Mac OS X, Mac OS 10.5 “leopard”, Linux etc.

Front panel 101 also includes 2 USB ports 108 coupled to touch screen computer 102. The USB ports 108 allow for the upload of software updates, calibration data or the like for given test points within the device/system under test etc. The USB ports 108 also allow for the download of test information collected for a given device/system. This information may be downloaded in a raw data format. The raw data may then be analysed by any suitable software suite depending on the level of analysis required. If required the unit 100 can provide a number of preformatted reports which can also be downloaded via the USB ports 108.

An Ethernet port 109 may also be provided on the front panel 101. The provision of the Ethernet port 109 allows for the unit to be linked into a Local Area Network (LAN) or Wide Area Network (WAN) to enable remote monitoring and testing for example a given point or node within the communications network, such as a base station. Software updates and calibration information may also be provided to the unit via the LAN or WAN through Ethernet port 109.

As briefly mentioned above the unit includes a number of internal system alarms which can be viewed by a user via navigating through the menu buttons 105a. The alarms for example may include a visual indicator of the operating status of the unit internal systems e.g. the unit's various High Power Amplifier (HPA), Low Noise Amplifier (LNA), Frequency Synthesiser circuits and the unit's internal voltage supply rails etc. These visual alarms may be implemented as hardware solution or in the unit's software. In addition to these visual alarm indicators the system may also provide a number of audible alarms. These alarms may also be further augmented by a warning indicator lamp 113 denoting the present of high frequency RF signals. The lamp 113 is constantly illuminated during the active test mode (i.e. button 104 set on).

While the unit provides the user with reliable measurements for example of system power, return loss and PIM products, port 110 is provided to allow auxiliary equipment such as a spectrum analyser to be connected to the test unit 100 during onsite testing.

To assist with ventilation and cooling of the unit's 100 internal components the front panel is provided with a plurality of ventilation slots 115. In addition to this an air gap may be provided between the outer periphery of the front panel 101 and the body of carry case 116b to further assist with cooling.

To assist with mounting and removal of the unit 100 from the carry case 116 handles 114a, 114b are provided. In addition to this the handles 114a, 114b can be used to slide the unit 100 in and out of, for example, a rack mounting arrangement. Providing the ability to rack mount the unit 100, allows for the unit 100 to be permanently positioned at for example a base station and linked back to a central monitoring station via for example the Ethernet port 109. Applicant also envisages that the unit 100 could in such instances could be wireless networked to the central monitoring station via a suitable wireless interface such as an 802.11a, b, g or n interface.

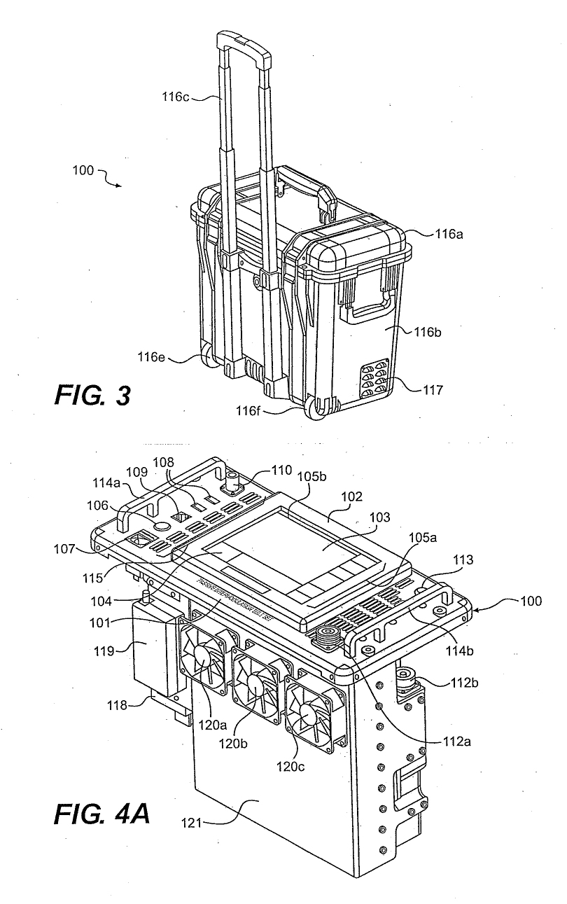

FIG. 2 shows the test unit 100 mounted with the carry case 116. As discussed above the test unit 100 is mounted within the case 116 so that the majority of the unit 100 is retained with the main body 116b of the carry case 116. This allows the front panel 101 to be mounted substantially flush upper lip of the carry case 116 so as to enable lid 116a to close over handles 114a, 114b in order to secure the test unit 100 for transport. As shown the main body 116b of the carry case 116 is provided with an exhaust fans 117 which vent hot air from the case 116 and draw cool air in through the ventilation slots 115 and the air gap provided between the main body 116b of the case 116 and the outer periphery of the front panel 101.

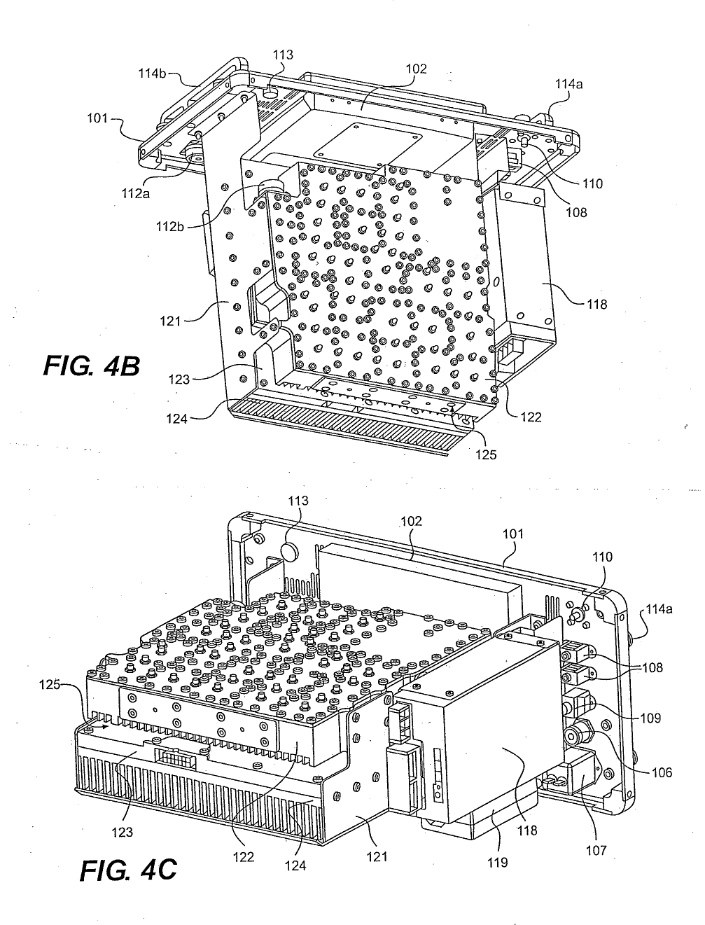

One possible configuration of the case containing the test unit readied for transport is shown in FIG. 3. In this instance lid 116a has been closed over front panel and secured to the main body 116b via lugs 116c, 116d (see FIG. 2). Handle 116c may then be extended, as shown, thereby allowing the case to be freely wheeled to and from the test site via wheels 116e, 116f.

In FIG. 4A the test unit 100 has been removed from case 116. Here the test unit's 100 main test modules can be seen, namely the filter assembly 122 and main control assembly 123. As shown the filter assembly 122 and main control assembly 123 are secured to a chassis 121 which inturn is secured to the rear of front panel 101. Mounted on the under side of the chassis 121 is a series of cooling fans 120a, 120b and 120c. The fans 120a, 120b and 120c force cool air onto and down the chassis 121 thereby drawing heat away from the main test modules.

The main power supply unit 118 in this instance is mounted to the side of chassis 121. Mounted directed below the main power supply unit is the power supply unit 119 for the touch screen computer 102. Also show in FIG. 4A is the filter assembly's 122 output port 112b which is coupled to via a suitably shielded connector to the main output port 112a on the front panel 101.

FIG. 4B is a top perspective view of the test unit as shown in FIG. 4A and further illustrates the arrangement of the test unit's 100 main test modules. Heat sink 124 in this instance is positioned against the chassis 121 on the adjacent side to that of the cooling fans 120a, 120b and 120c. The main control assembly 123 is inturn mounted directly above the heat sink 124. Likewise the filter assembly 122 is mounted above the main control assembly 123 such that there is an air gap 125 between these two sections.

The air gap 125 provided between the control assembly 123 and the filter assembly 122 is emphasised in FIG. 4C. As can bee seen from FIG. 4C the gap 125 between the two modules is such that it allows for sufficient air flow around the filter assembly 122 and across the upper surface of the control assembly 123 to further assist cooling of the unit 100.

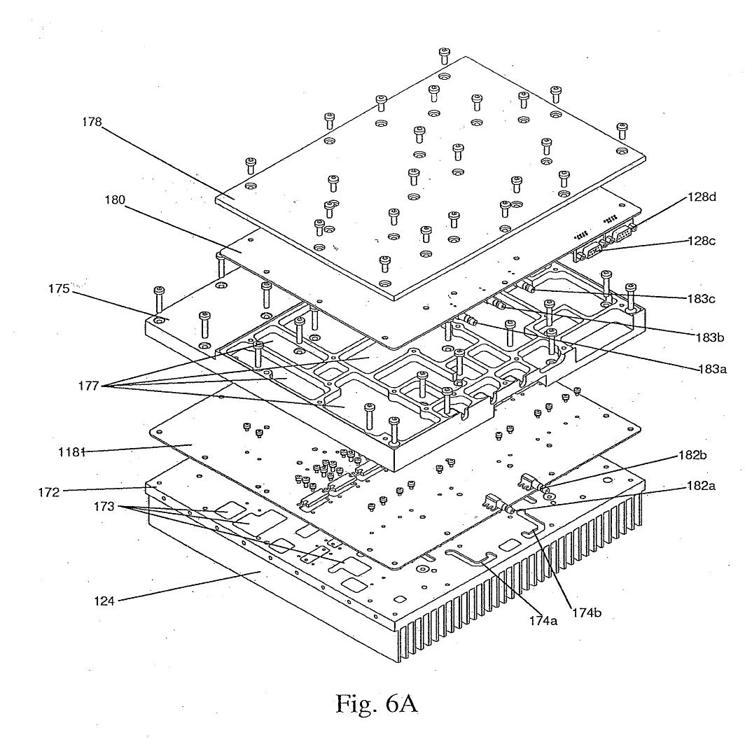

With reference to FIG. 4D there is illustrated a further bottom perspective view of the test unit 100 according to FIGS. 4A to 4C as discussed above. Shown here are the various input/output ports of the flat panel touch screen computer 102, which in this case include two USB ports 126 which are coupled to the USB ports 108 on the front panel 101. The flat panel touch screen computer 102 also includes at least one Ethernet port 127 which is coupled to the Ethernet port 109 on the front panel 101 via a suitable pass through cable. In addition to the USB 126 and Ethernet ports 127, the flat panel touch screen computer 102 is provided with a pair of 9-pin D-sub connectors 128a, 128b which are coupled to the D-sub connectors 128c, 128d on the RF control board 130 (see FIGS. 6A and 6B).

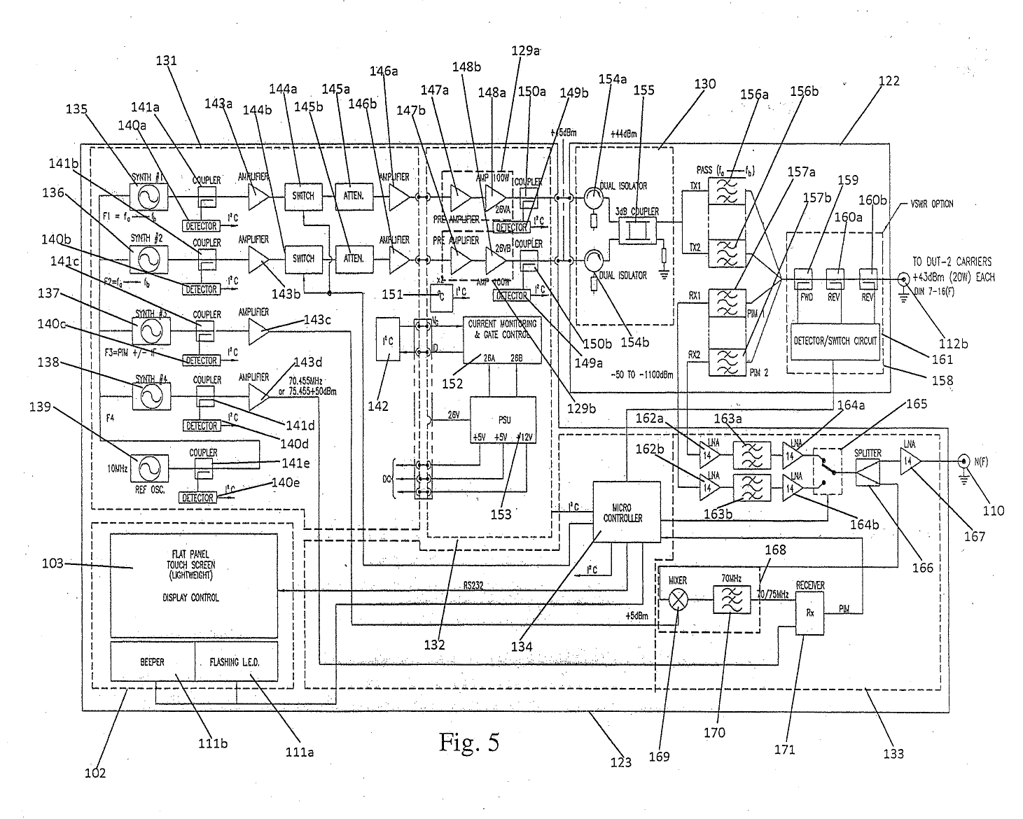

FIG. 5 is system schematic of the test unit 100 of FIGS. 1 through to 4B further detailing the interconnection between the various test modules of the unit 100. As shown the control assembly 123 includes a number of modules, the frequency synthesiser module 131, power amplifier and power supply (HPA/PSU) module 132, receiver module 133, and main processor 134.

As shown, the synthesiser module 131 in this particular example includes four frequency synthesisers 135,136,137,138. The first and second frequency synthesisers 135, 136 provide the test unit's 100 transmitter frequencies, while third and fourth frequency synthesisers 137, 138 provide reference frequencies to the receiver module 133. The synthesisers 135,136,137,138 are coupled to a reference oscillator 139 which provides a reference signal of 10 MHz to each. The operating status of each of the synthesisers 135,136,137,138 and the reference oscillator 139 are monitored by a plurality of detectors 140a, 140b, 140c, 140d and 140e which are connected to the output of each via couplers 141a, 141b, 141c, 141d and 141e. The output of detectors 140a, 140b, 140c, 140d and 140e are then coupled via an I²C bus to the bus controller 142 which is in turn coupled main processor 134.

The output arm of each of the couplers 141a, 141b, 141c and 141d associated with synthesisers 135,136,137,138 are passed to a set of amplifiers 143a, 143b, 143c and 143d. The output of amplifiers 143a and 143b are then coupled to switches 144a 144b. The switches 144a, 144b are used to toggle the output transmission frequency between that supplied by the first synthesiser 135 and the second synthesiser 136. The operation of switches 144a and 1434 are directly controlled the main processor 134. The outputs from each of the switches 144a, 144b are coupled to attenuators 145a, 145b. The attenuators 145a, 145b are in turn coupled to amplifiers 146a and 146b.

The output signals from amplifiers 146a and 146b are then passed to the pre-amplifier stages 147a, 147b respectively of the high power amplifiers 129a, 129b provided on the HPA/PSU module 132. The outputs of the pre-amplifiers 147a, 147b stages are then feed to their respective power amplifier sections 148a and 148b. Here the output of the power amplifier stages 148a, 148b are monitored by a pair of detectors 149a and 149b connected to the output of each via couplers 150a, 150b. Again the detectors 149a and 149b are coupled via the I²C bus to the bus controller 142.

Also provided on the HPA/PSU module 132 are temperature sensor 151 and a current monitoring and gate control module 152, both of which are coupled via the I²C bus to the bus controller 142. In the present example the temperature sensor 151 is set to initiate a thermal shutdown via the I²C bus of the test unit 100 on detection of an operating temperature in excess of approximately 70° C.

As shown, the current monitoring and gate control module 152 is also coupled to the voltage regulation module 153. The voltage regulation module 153, in this instance, not only provides the regulated +5, +12 and 26 voltage supply rails, but also provides a reference supply for the current monitoring and gate control module 152. Based on the information provided by the detectors via the I²C bus the current monitoring and gate control module 152 can detected current fluctuation in current in various points within the unit 100 and initiate appropriate corrective action via the I²C bus controller 142. Likewise, if the current monitoring and gate control module 152 detects a fault in a gate or number of gates it can initiate appropriate corrective action such as closing down the section containing the malfunctioning gate or gates etc.

The filter assembly 122 in this case includes a combiner 130 which includes a pair of dual isolators 154a, 154b. The inputs for each of the dual isolators 154a, 154b are coupled to the output of the respective power amplifier sections 148a and 148b. The output of each of the isolator is fed to a 3 dB coupler 155 the output of which is coupled to a pair of bandpass filters 156a, 156b.

The bandpass filters 156a, 156b are tuned to the desired transmission frequency bands. The output of each filter 156a, 156b is then coupled to the output port of the filter assembly 112b. Also coupled to the output port 112a are a pair of bandpass filters 157a, 157b which are tuned to the desired reception frequency bands. It will be appreciated by those of ordinary skill in the art that while the filters are shown as two separate bandpass filters or they could be 1 or 2 filters diplexed.

The filer assembly may optionally include a Voltage Standing Wave Ratio (VSWR) monitor 158. In the current example the VSWR monitor 158 includes at least one forward coupler 159 and two reverse couplers 160a, 160b. The VSWR monitor 158 is positioned between the output of the transmission filters 156a, 156b and the input of the reception filters 157a, 157b. The forward 159 and reverse couplers 160a, 160b are connected to a detector/switch circuit 161 which inturn is coupled the main processor 134.

The output of the reception filters 157a, 157b are coupled to a pair of low noise amplifiers 162a, 162b in the receiver module. The outputs of each of these amplifiers 162a, 162b are then fed to bandpass filters 163a, 163b. The filtered signals are then passed to low noise amplifiers 164a, 164b the outputs of which are coupled to a switch 165. The switch 165 allows the processor 134 to toggle reception between the two receiver paths (i.e. the outputs provided by bandpass filters 157a, 157b). The output of the switch is then coupled to splitter 166, which has one arm connected to the auxiliary output port 110 via a low noise amplifier 167. The remaining arm of the splitter is passed to the down converter 168, which in this case comprises mixer 169 coupled to a lowpass filter 170. The output from amplifier 143c is also connected to the down converter 168 via mixer 169. The output of the down converter 168, from lowpass filter 170 is then fed to receiver 171. The receiver also is coupled to the output of amplifier 143d which provides a reference signal for the receiver 171. The output of the receiver is then passed to the main processor 134.

As illustrated the main processor 134 is also coupled to the touch screen PC 102 via an RS232 link. The main processor 134 may also be linked to additional alarm indicators such as a beeper/buzzer 111a and a plurality of flashing LEDs 111b to augment the alarms provided under the unit's system software.

As can be seen from both FIGS. 4B and 4C the unit 100 employs a vertically stacked configuration. It is the notion of stacking the various modules in this manner that has allowed the applicant to incorporate the various test modules in a single, compact, portable unit. In the present case a significant size and weight reduction has been achieved through the design of novel multilayer control boards housed within the control assembly 123.

As will be appreciated by those of ordinary skill in the art, when various high power RF components are brought into close relation isolation becomes critical. The applicant has found through the design of their novel control boards and the outer housing of the control assembly 123 they can achieve a high level of isolation between the various components disposed on the boards. The design of the control boards and the control unit housing are discussed in greater detail below.

FIGS. 6A and 6B depict exploded views of the main control assembly 123 of the test unit 100 according to embodiment of the present invention. The main control assembly 123 in this instance contains two PCBs, the main RF control PCB 180 and the high power amplifier and power supply HPA/PSU control board 181. The boards 180, 181 in this instance are mounted in a stacked configuration within housing 184. The housing 184 here is composed of three sections a base 172 which may, as in this instance, may be formed integral with the heat sink 124, a mid section 175 and a top plate 178.

The base 172 includes a plurality of recessed portions 173, which act to compartmentalise the various components on the underside of the HPA/PSU board 181. Also shown here are two channels 174a, 174b these channels enable the tracks linking the outputs of the high power amplifiers 124a, 124b with their respective output connectors to be minimised while maintaining track integrity.

Once the HPA/PSU control board 181 is secured to the base plate, the mid section 175 of the housing 184 is positioned directly over the upper-side of the HPA/PSU control board 181. As with the base 172, the mid section 175 includes a plurality of recess 176 on its lower side and a plurality of recess 177 (see FIG. 6B) on its upper surfaces, these recesses act to compartmentalise the components on the upper side of the HPA/PSU control board 181 and the under-side of the RF control board 180 (as shown in FIGS. 6A and 6B).

Once the mid section 175 is secured over the HPA/PSU control board 181, the RF control board is then secured to the mid section 175. To complete the construction a top plate 178 is then fasted over the upper surface of the RF control board 180. As with the base plate 172 and mid section 175 the top plate also contains a number of recesses 179 which act to compartmentalise the components on the upper-side of the RF control board 180.

Also shown in FIGS. 6A and 6B are a pair of output connectors 182a, 182b disposed on the HPA/PSU board, for the high power amplifiers 124a, 124b which are coupled to the inputs of the combiner 189 on the filter assembly 122. The RF control board includes two input connectors 183a, 183b which are coupled to the outputs of the reception filters 157a,157b housed in the filter assembly 122. The RF control board also includes an output connector 183c which is coupled to the auxiliary output 110 on the front panel 101.

The compartmentalisation of the various components of each board provides some level of isolation. However, the applicant has found that higher levels of isolation can be achieved by through the co-operation of the housing elements, namely the base 172, the mid section 175 and top cover plate 178 engage the RF and HPA/PSU control boards 180,181.

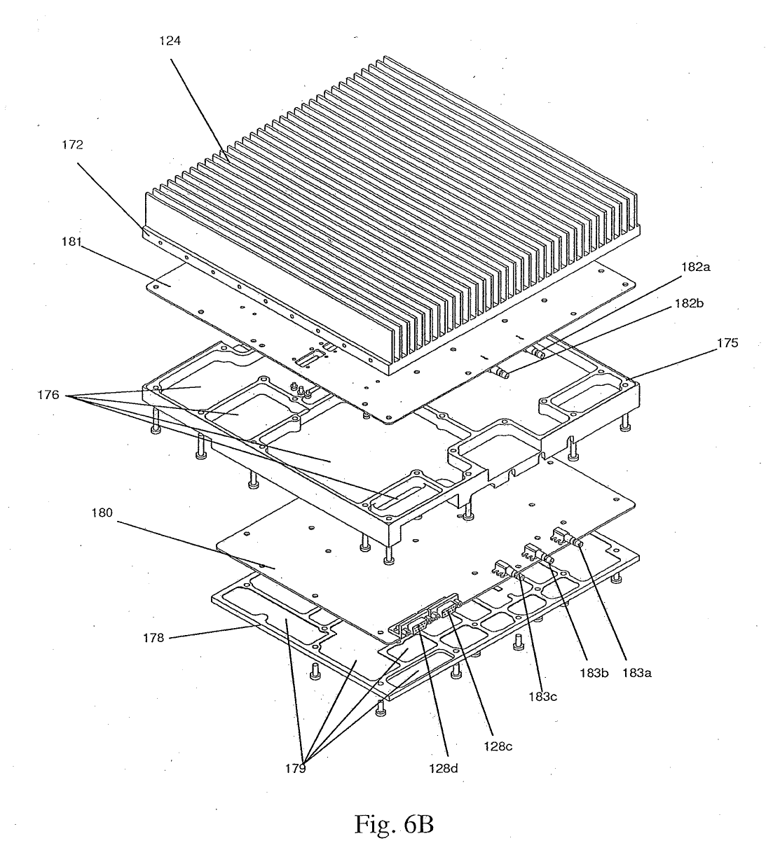

FIG. 7 shows the layout of one of the control board according to one embodiment of the present invention. As illustrated the board includes a series of exposed surface regions 190 dividing the board into a number of sections 191. The positioning of the exposed surface regions 190 matches the points at which the edges of the recess 173, 176 and 177 provided in the base 172, the mid section 175 and top cover plate 178 contact the boards 180, 181. During construction of the control assembly 123 the edges of the recesses 173, 176 and 177 are caused to bite down into the exposed surface regions 190 of the boards 180,181. It is this interaction between the board and the housing that further enhances the level of electrical isolation.

The multilayer construction of the boards 180, 181 would typically have the interconnects between various modules disposed on the boards 180, 181 disposed on all four sides of the board. The applicant's novel design however provides for a single surface interconnect zone, whereby the interconnects between various modules are disposed in a single region on the boards 180, 181. This arrangement offers a number of advantages in both maintenance and factor testing of the boards before deployment.

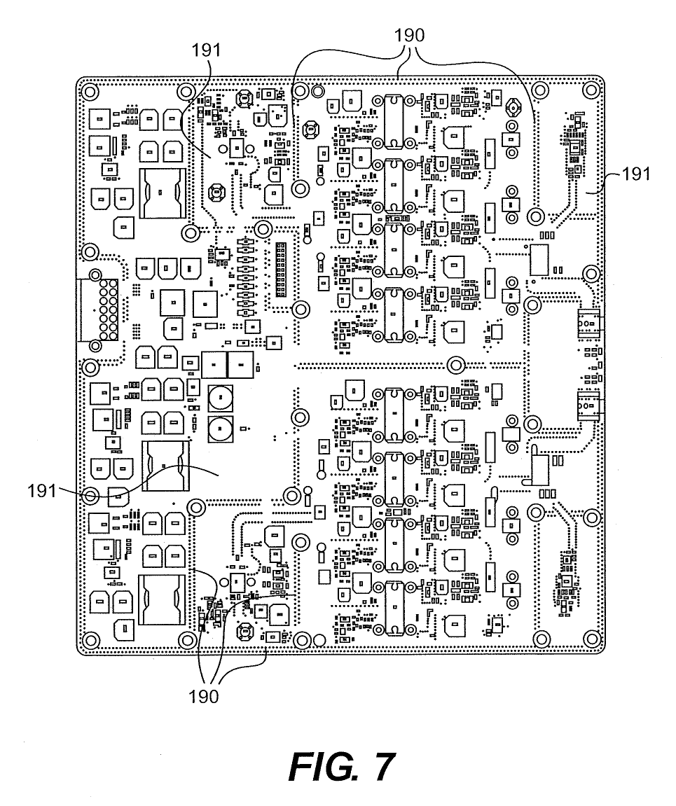

With reference to FIG. 8 there is illustrated a one possible arrangement of an optional internal load 185 according to one embodiment of the present invention. In this particular instance the load 185 is a filtered load, which includes at least one filter 186 and a resistor 187. The filter 186 may be a bandstop, a bandpass or a suitable filter network, the resistor 187 is preferable a 50Ω, 50 watt resistor. The filtered load is coupled via output connector 188 to an output port which may be provided on the front panel 101 (not shown).

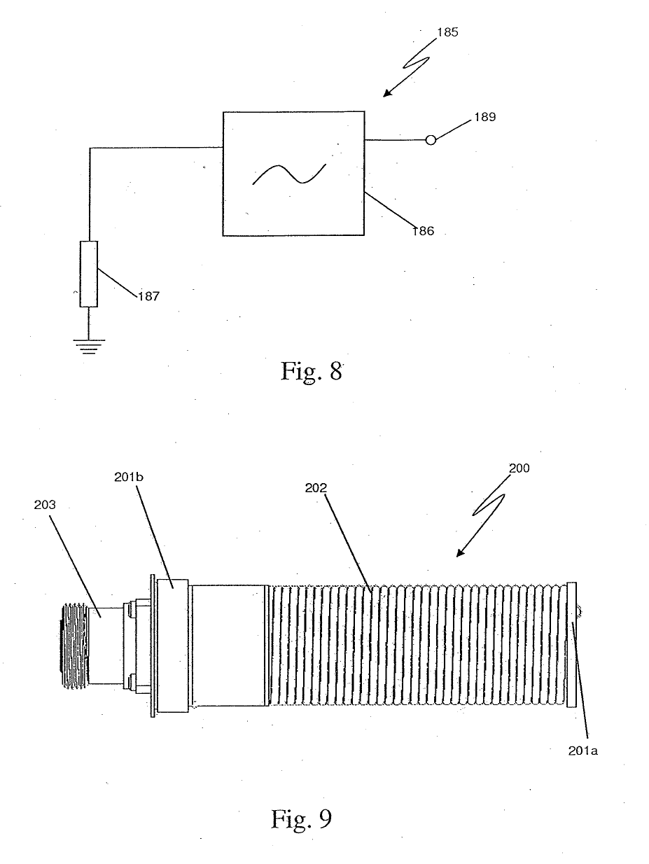

FIG. 9 illustrates on possible configuration of an external cable load 200 according to one embodiment of the present invention. The load consist of a hollow body, having an upper and lower collar 201a, 201b which form a spool therebetween. A cable load 202 is then wound about the spool. The free end of the cable load 202 is then fed down through the hollow body and terminates in connector 203. The connector 203 is any suitable RF connector, in the present case the connector 203 is a standard DIN connector.

It is to be understood that the above embodiments have been provided only by way of exemplification of this invention, and that further modifications and improvements thereto, as would be apparent to persons skilled in the relevant art, are deemed to fall within the broad scope and ambit of the present invention described herein.

1. A portable test apparatus for a communications device/system said apparatus comprising:
a display for displaying test information from the communications device/system;
a filter assembly; and
a control assembly comprising at least one printed circuit board and a housing wherein the at least one printed circuit board (PCB) and the housing co-operate to electrically isolate one or more components disposed on said at least one printed circuit board.

2. The apparatus of claim 1 wherein said filter assembly and the control assembly are arranged in a stacked configuration relative to one another.

3. The apparatus of claim 2 wherein the filter assembly and the control assembly are stacked in vertical relation.

4. The apparatus of claim 3 wherein the filter assembly and the control assembly are stacked linearly on top of one another.

5. The apparatus of claim 1 wherein the housing engages one or more exposed surface regions on said at least one PCB to electrically isolate one or more components disposed on said at least one printed circuit board.

6. The apparatus of claim 1 wherein the one or more components comprises a main processor coupled to at least one high power amplifier module, at least one receiver module, at least one frequency synthesiser, at least one voltage regulator module, a temperature sensor and current monitor and gate control module.

7. The apparatus of claim 6 wherein the control assembly further comprises a plurality of detectors which monitor the operating status of the one or more components, said plurality of detectors being coupled via an I²C bus to an I²C bus controller.

7. The apparatus of claim 1 wherein the display is a flat panel touch screen PC.

8. The apparatus of claim 7 wherein the display further comprises a dedicated area for displaying information relating to the current test point within the device/system under test and/or one or more operating parameters of the apparatuses.

9. The apparatus of claim 7 wherein the display further comprises one or more buttons for navigating one or more menus provided within the apparatus.

10. The apparatus of claim 7 wherein the display further comprises a power on/off button for initiating and terminating a selected test mode.

11. The apparatus of claim 10 wherein the test mode is selected from one of the following a power test mode, a return loss test mode or a passive intermodulation test mode.

12. The apparatus of claim 1 wherein the apparatus provides at least two output frequency tones.

13. The apparatus of claim 12 wherein the frequency tones are selected from a range of about 800 MHz to 1000 MHz.

14. The apparatus of claim 12 wherein the frequency tones are selected from a range of about 1700 MHz to 2200 MHz.

15. The apparatus of claim 1 wherein the apparatus further comprises at least one port for the attachment of an auxiliary device.

16. The apparatus of claim 15 wherein the auxiliary device is a spectrum analyser or a power meter.

17. The apparatus of claim 1 wherein the apparatus further comprises at least one network interface and at least one serial interface.

18. The apparatus of claim 1 wherein the filter assembly further comprises a combiner, at least one transmission filter and at least one reception filter.

19. The apparatus of claim 17 wherein the transmission and reception filters are bandpass filters and the combiner comprises at least one dual isolator and a 3 dB coupler.

20. The apparatus of claim 17 wherein the filter assembly further comprises at least one Voltage Standing Wave Ratio (VSWR) monitor.

21. The apparatus of claim 17 wherein the VSWR comprises at least one forward coupler and at least one reverse coupler, coupled to a detector/switching circuit.

22. A portable test apparatus for a communication device/system said apparatus comprising:
a display for displaying test information from the communications device/system;
a filter assembly;
a control assembly comprising a first printed circuit board, a second printed circuit board and a housing; and
wherein the housing is constructed from a plurality of segments which co-operate with said first and second printed circuit board and the housing to electrically isolate one or more components disposed on said at least one printed circuit board.
